(19) United States
(12) Patent Application Publication
(10) Pub. No.: US 2010/0085096 A1
(43) Pub. Date: Apr. 8, 2010

(54) ENERGY-EFFICIENT CLOCK SYSTEM

(75) Inventors: Nicholas H. SCHUTT, Villeneuve-Loubet (FR); Karl F. GREB, Missouri City, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/360,953

(22) Filed: Jan. 28, 2009

Related U.S. Application Data
(60) Provisional application No. 61/103,114, filed on Oct. 6, 2008.

(51) Int. Cl. H03L 7/00

(52) U.S. Cl. 327/161; 327/141

(57) ABSTRACT

A system comprises first timing logic configured to produce a first signal and second timing logic configured to produce a second signal. The system also comprises processing logic coupled to the first and second timing logic. The system further comprises clock logic that determines elapsed time using the first signal. The processing logic compares the first and second signals and, based on the comparison, the system adjusts the elapsed time.

### CROSS-REFERENCE TO RELATED APPLICATIONS

This application claims the benefit of U.S. Provisional Application Ser. No. 61/103,114, filed Oct. 6, 2008, titled “Extended Temperature Clock Calibration Technique for Automotive Applications,” and incorporated herein by reference as if reproduced in full below.

### BACKGROUND

Various hardware and software applications require accurate clock signals to perform their respective functions. Standard, low-frequency oscillators produce clock signals of poor accuracy, particularly in harsh environments that include extreme temperatures. More accurate, high-frequency oscillators often are unsustainable due to the additional power demands introduced by such oscillators.

### SUMMARY

The problems noted above are solved in large part by an accurate and energy-efficient clock system. An illustrative embodiment includes a system that comprises first timing logic configured to produce a first signal and second timing logic configured to produce a second signal. The system also comprises processing logic coupled to the first and second timing logic. The system further comprises clock logic that determines elapsed time using the first signal. The processing logic compares the first and second signals and, based on the comparison, the system adjusts the elapsed time.

Another illustrative embodiment includes a system that comprises first and second timing logic, where the second timing logic operates at a higher frequency than does the first timing logic. The system also comprises processing logic coupled to the first and second timing logic. During a period of time, the first timing logic continuously produces a first signal and the second timing logic intermittently produces a second signal. The processing logic compares the first and second signals and uses the comparison to adjust system clock logic.

Yet another illustrative embodiment includes a method that comprises first timing logic producing a first signal and activating second timing logic to produce a second signal. The method also comprises processing logic comparing pulses produced by each timing logic during a common period of time to a quantity of pulses expected from each timing logic. The method further comprises deactivating the second timing logic and adjusting system clock logic based on the comparison.

### BRIEF DESCRIPTION OF THE DRAWINGS

For a detailed description of exemplary embodiments of the invention, reference will now be made to the accompanying drawings in which:

FIG. 1 shows a block diagram of an illustrative system implemented in accordance with various embodiments;

FIG. 2 shows a flow diagram of an illustrative method implemented in accordance with embodiments; and

FIG. 3 shows an illustrative, motorized transportation apparatus implementing the techniques disclosed herein, in accordance with embodiments.

### NOTATION AND NOMENCLATURE

Certain terms are used throughout the following description and claims to refer to particular system components. As one skilled in the art will appreciate, companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . .” Also, the term “couple” or “couples” is intended to mean either an indirect or direct electrical connection. Thus, if a first device couples to a second device, that connection may be through a direct electrical connection, or through an indirect electrical connection via other devices and connections. The terms “processor” and “processing logic” are analogous.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

Disclosed herein is an accurate, energy-efficient clocking system. The system includes a low-frequency oscillator. A real-time clock uses the low-frequency oscillator to track time. However, as noted, low-frequency oscillators can produce inaccurate clocking signals, particularly in extreme temperatures. Thus, the clocking system also includes a high-frequency oscillator. The high-frequency oscillator remains in an inactive, power-conserving state for most of the time. However, the high-frequency oscillator is intermittently activated and its clocking signal compared to the clocking signal of the low-frequency oscillator. Because the high-frequency oscillator is more accurate than the low-frequency oscillator, the results of this comparison indicate the degree to which the low-frequency oscillator has “gotten off-track” (i.e., the inaccuracy/drift that has crept into the low-frequency oscillator's clocking signal). Thus, after the clocking signals have been compared, the high-frequency oscillator is again shut off and the results of the comparison are used to adjust (i.e., calibrate) the real-time clock. This process is repeated intermittently to ensure that the accuracy of the low-frequency clock stays within acceptable limits. Further, because the high-frequency oscillator remains in an inactive, power-conserving state for most of the time, power is conserved.

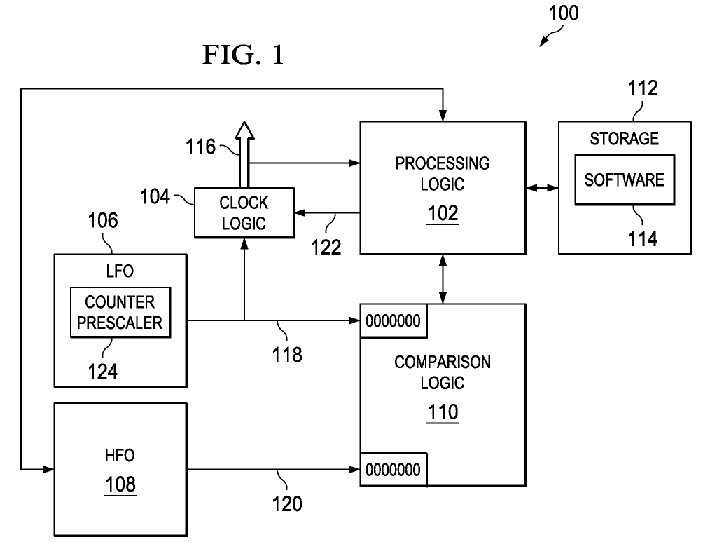

FIG. 1 shows a block diagram of an illustrative system 100 implemented in accordance with various embodiments. The system 100 includes processing logic 102 (e.g., processor or central processing unit), clock logic 104 that tracks elapsed time (e.g., seconds, minutes, hours, days, weeks, etc.), low-frequency oscillator (LFO, or “timing logic”) 106, high-frequency oscillator (HFO, or “timing logic”) 108, comparison logic 110 (e.g., a hardware clock comparator), storage 112 and software 114. In at least some cases, when the processing logic 102 is described herein as performing a function, that performance is caused at least in part by execution of the software 114.

The LFO 106 generally operates at a lower frequency (e.g., 32 kHz) than does the HFO 108 (e.g., 20 MHz), but the operational frequencies of both the LFO 106 and HFO 108 are variable. The LFO 106 produces a clocking signal 118 that the clock logic 104 uses to keep track of elapsed time. A real-time clock signal 116 is produced by the clock logic 104 to indicate elapsed time and may be used as desired. The technique disclosed herein is used to maintain the accuracy of the clock signal 116 produced by the clock logic 104.

The HFO 108 generates a high-frequency clocking signal 120 that is provided to the comparison logic 110. The HFO 108, by virtue of its greater operational frequency, produces a clocking signal that maintains greater accuracy over time and environmental conditions (e.g., extreme temperature, voltage, etc.) than does the LFO 106. Thus, the high-frequency clocking signal 120 is used intermittently to correct the low-frequency clocking signal 118 in case the accuracy of the signal 118 has exceeded some predetermined margin of error. Stated in another way, the high-frequency clocking signal 120 is used as the “correct” clocking signal, or the “standard” reference signal, against which the accuracy of the low-frequency clocking signal 118 is gauged.

Although it is more accurate, the HFO 108 consumes more power than does the LFO 106. Thus, the HFO 108 generally is kept in an inactive, power-conserving state. The HFO 108 is intermittently activated (e.g., every 10 minutes) for a short period of time (e.g., 1-2 seconds) to “check on” the performance of the LFO 106. The comparison logic 110 compares the low-frequency clocking signal 118 against the high-frequency clocking signal 120 as follows. The LFO 106 begins in an active state, while the HFO 108 begins in an inactive, power-conserving state. After a predetermined amount of time passes (e.g., 10 minutes, as determined by the clock logic 104), the processing logic 102 activates the previously inactive HFO 108. The processing logic 102 also causes the comparison logic 110 to begin counting the pulses in each of the clocking signals 118, 120. After a predetermined amount of time has passed (e.g., 1-2 seconds, as determined by the clock logic 104), the processing logic 102 causes the comparison logic 110 to stop counting pulses, and further causes the HFO 108 to return to an inactive, power-conserving state. The comparison logic 110 provides the number of pulses counted from each of the clocking signals 118,120 to the processing logic 102.

In turn, the processing logic 102 compares the counted pulses against an expected number of pulses (e.g., stored in software 114). For example, if the LFO 106 operates at 32 kHz and the HFO 108 operates at 20 MHz, in the span of one second, the processing logic 102 may expect the comparison logic 110 to count 32,000 pulses from the LFO 106 and 20,000,000 pulses from the HFO 108. However, if, during that period of time, the comparison logic 110 counts 20,000,000 pulses from the HFO 108 but only counts 25,600 pulses from the LFO 106, the LFO 106 evidently has slowed down (i.e., drifted). As a result, the clock logic 104 is producing a real-time clock signal 116 that is inaccurate in that the elapsed time indicated in the signal 116 is “behind.” For example, if the signal 116 indicates that the current time is 2:00 PM, the time may, in reality, be 2:01 PM. Thus, the signal 116 should be adjusted.

The processing logic 102 adjusts the signal 116 by sending a correction signal (i.e., comprising a correction value) 122 to the clock logic 104. In some embodiments, the correction signal 122 is generated by the processing logic 102 by taking into account what the actual time should be, given the fact that the LFO 106 is not operating at the proper speed. Other techniques for generating the correction signal 122 also may be used, as desired. The clock logic 104 receives the correction signal 122 and corrects the real-time clock signal 116 accordingly. For example, if the LFO 106 is determined to be 1,000 pulses behind the expected number of pulses, the software 114 may cause the processing logic 102 to “translate” the 1,000 pulses into a particular unit of time. For instance, if each pulse is equal to 1 millisecond, and if the LFO 106 is 1,000 pulses behind, then the real-time clock signal 116 (the “time-elapsed” signal) produced by the clock logic 104 is determined to be 1 second behind (1 millisecond per pulse multiplied by 1,000 pulses). Thus, the correction signal 122 indicates to the clock logic 104 that the time elapsed, as indicated in signal 116, should be advanced by 1 second.

The comparison described above may be performed using ratios. For example, the software 114 may indicate that the expected pulse ratio between a 20 MHz HFO 108 and a 32 kHz LFO 106 may be 625:1. If, during a common period of time (regardless of the length of the period of time), the actual pulse ratio between the HFO 108 and the LFO 106 does not meet the expected ratio of 625:1, the clock logic 104 may be adjusted as necessary. Thus, for instance, if the actual ratio is higher than the expected ratio, the clock logic 104 may be adjusted so that the elapsed time is increased. Similarly, if the actual ratio is lower than the expected ratio, the clock logic 104 may be adjusted so that the elapsed time is decreased. In some embodiments, the software 114 may be programmed with specific tolerances. In these embodiments, if the difference in ratios falls between these tolerances, no action is taken. However, if the difference in ratios falls on our outside these tolerances, action is taken as described above. In at least some embodiments, the comparison process described above is completed entirely or in part by the comparison logic 110.

The LFO 106 may comprise a counter prescaler 124. The prescaler 124 comprises an electronic counting circuit used to reduce electrical signal frequency (e.g., by integer division). In at least some embodiments, the results of the comparison described above are used to adjust the prescaler 124 so as to reduce LFO 106 error in producing subsequent clocking signals 118.

Because the processing logic 102 uses software 114 to perform the comparisons, calculations and corrections described above, the system 100 is afforded greater flexibility than are solutions that do not use the techniques disclosed herein. For example, because the processing logic 102 and software 114 are configured to perform the disclosed technique using relative numbers and ratios, the signals produced by the LFO 106 and HFO 108 do not need to be of a permanently-fixed frequency. The LFO 106 and HFO 108 frequencies may be varied as desired, as long as the processing logic 102/software 114 is kept apprised of the expected number and/or ratio of pulses from each oscillator (e.g., by updating the software 114).

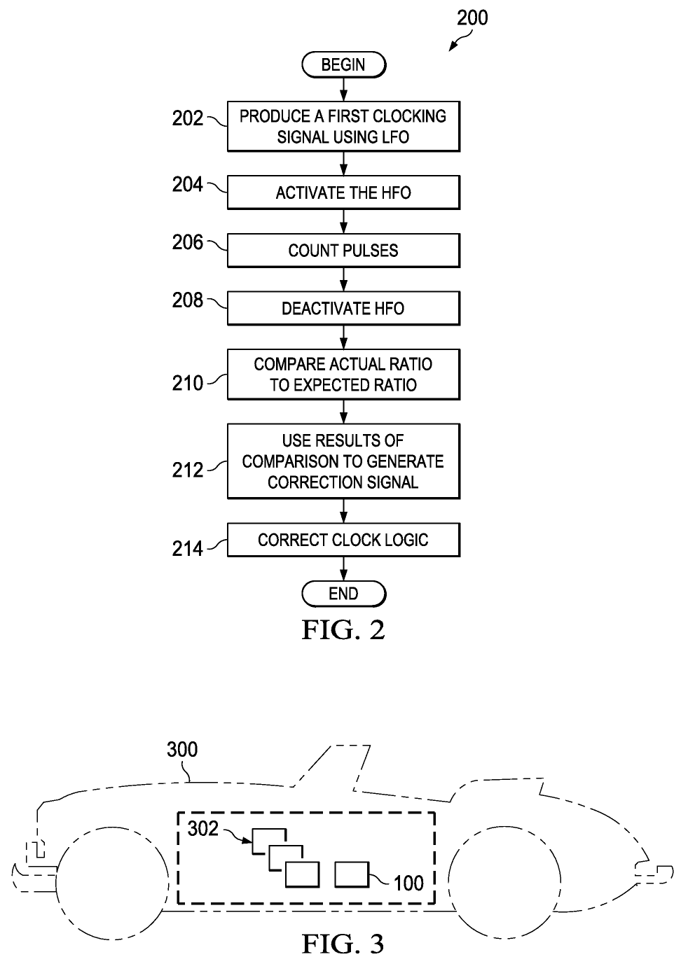

FIG. 2 shows a flow diagram of an illustrative method 200 implemented in accordance with embodiments. The method 200 begins with the LFO 106 producing a first clocking signal (block 202). The method 200 then comprises the processing logic 102 activating the previously-inactive HFO 108 (block 204). The method 200 also comprises the comparison logic 110 counting the pulses produced by each of the LFO 106 and HFO 108 during a common period of time (block 206). The method 200 comprises deactivating the HFO 108 (block 208). The method 200 further comprises the processing logic 102 comparing the actual ratio of counted pulses to the expected ratio of counted pulses (block 210). The method 200 still further comprises using the results of the comparison to generate a correction signal 122 usable to adjust the clock logic 104 and the output signal 116 of the clock logic 104 (block 212). The method 200 still further comprises using the correction signal 122 to adjust the clock logic 104 and the output signal 116 of the clock logic 104 (block 214). The process shown in FIG. 2 may be repeated at regular or irregular intervals. Further, the steps of method 200 may be adjusted as desired (i.e., steps may be added, deleted and/or rearranged).

FIG. 3 shows an illustrative, motorized transportation apparatus 300 implementing the techniques disclosed herein, in accordance with embodiments. Specifically, the apparatus 300 comprises the system 100 and contains various hardware and/or software applications 302 that use the real-time clock signal 116 produced by the clock logic 104. The apparatus 300 may comprise a car, truck, airplane, train, SEGWAY®, motorcycle, all-terrain vehicle, golf cart, etc.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A system, comprising:
first timing logic configured to produce a first signal;
second timing logic configured to produce a second signal;
processing logic coupled to the first and second timing logic; and
clock logic that determines elapsed time using the first signal;
wherein the processing logic compares the first and second signals and, based on said comparison, the system adjusts said elapsed time.

2. The system of claim 1, wherein the second timing logic operates at a higher frequency than does the first timing logic.

3. The system of claim 1, wherein the system comprises an automobile.

4. The system of claim 1, wherein, during a period of time, the first timing logic continuously produces the first signal while the second timing logic intermittently produces the second signal.

5. The system of claim 4, wherein, during said period of time, the second timing logic is in a power-conserving, inactive state when the second timing logic is not producing said second signal.

6. The system of claim 1, wherein the comparison logic compares the first and second signals by counting pulses of each of the signals for a common period of time and then determining a difference between the number of pulses associated with each of said signals.

7. The system of claim 1, wherein the processing logic uses the comparison to determine the accuracy of the first timing logic.

8. The system of claim 1, wherein the first timing logic uses a counter prescaler to produce first signal, and wherein said comparison is used to adjust the counter prescaler.

9. A system, comprising:
first and second timing logic, the second timing logic operates at a higher frequency than does the first timing logic; and
processing logic coupled to the first and second timing logic;
wherein, during a period of time, the first timing logic continuously produces a first signal and the second timing logic intermittently produces a second signal;
wherein the processing logic compares the first and second signals and uses said comparison to adjust system clock logic.

10. The system of claim 9, wherein the processing logic compares the first and second signals by determining a ratio of the first and second signals and by comparing said ratio to an expected ratio of the first and second signals.

11. The system of claim 9, wherein processing logic uses said comparison to correct an elapsed time value produced using the clock logic.

12. The system of claim 9, wherein the system clock logic uses the first signal to produce a system clock signal that indicates elapsed time.

13. The system of claim 9, wherein the first signal has a variable frequency and the second signal has a variable frequency.

14. The system of claim 9, wherein, during said period of time, the second timing logic is in a power-conservation mode when not producing said second signal.

15. The system of claim 9, wherein the first timing logic produces the first signal using a counter prescaler, and wherein system uses said comparison to adjust the counter prescaler.

16. A method, comprising:
first timing logic producing a first signal;
activating second timing logic to produce a second signal;
processing logic comparing pulses produced by each timing logic during a common period of time to a quantity of pulses expected from each timing logic;
deactivating said second timing logic; and
adjusting system clock logic based on said comparison.

17. The method of claim 16, wherein activating said second timing logic comprises adjusting the second timing logic from an inactive, power-conserving state to an active state, and wherein deactivating said second timing logic comprises adjusting the second timing logic from an active state or an inactive, power-conserving state.

18. The method of claim 16, further comprising:
the first timing logic producing said first signal using a counter prescaler; and
adjusting said counter prescaler using said difference.

19. The method of claim 16, further comprising operating said first timing logic at a lower frequency than the second timing logic, and wherein said frequencies of the first and second timing logic are variable.

20. The method of claim 16, further comprising installing said first and second timing logic in a motorized transportation apparatus, generating a system clock signal using the adjusted system clock logic, and using the system clock signal in high-temperature applications within the motorized transportation apparatus.
